(19) United States
(12) Patent Application Publication
(10) Pub. No.: US 2014/0264936 A1
(43) Pub. Date: Sep. 18, 2014

(54) SEMICONDUCTOR PACKAGE

(71) Applicant: Samsung Electronics Co., Ltd., Suwon-si (KR)

(72) Inventors: Seung Youl CHOI, Seoul (KR); Jun Hyung KIM, Suwon-si (KR); Byung Hyun LEE, Seongnam-si (KR)

(73) Assignee: Samsung Electronics Co., Ltd., Suwon-si (KR)

(21) Appl. No.: 14/201,307

(22) Filed: Mar. 7, 2014

(30) Foreign Application Priority Data
Mar. 13, 2013 (KR) 10-2013-0026771

(51) Int. Cl. H01L 23/48

(52) U.S. Cl. CPC H01L 23/481
USPC 257/774

(57) ABSTRACT

A semiconductor package including a first connection terminal group configured to receive a first signal group from the outside of the semiconductor package, a second connection terminal group configured to transmit a second signal group to the outside, a first chip connected to the first connection terminal group, and a second chip connected to the second connection terminal group and configured to receive the first and second signal groups from the first chip. Degradation of the performance of the semiconductor package, caused by the differences between signal delay times in a plurality of chips therein may be minimized.

### CROSS-REFERENCE TO RELATED APPLICATIONS

This application claims the benefit of priority to Korean Patent Application No. 10-2013-0026771, filed on Mar. 13, 2013, in the Korean Intellectual Property Office, the disclosure of which is incorporated herein in its entirety by reference.

### BACKGROUND

Embodiments of the present disclosure relate to a semiconductor package, and more particularly, to a semiconductor package having an internal structure capable of minimizing a signal delay between chips therein.

As digital information appliance products, e.g., a smart phone, a digital camera, and a personal digital assistant (PDA), have been developed to be smaller, lighter, and multi-functional, and to have high performance, semiconductor packages are typically required to be smaller, lighter, and highly integrated. In addition, much attention has been paid to three-dimensional (3D) semiconductor technology whereby a plurality of semiconductor chips are mounted in one package. The chips in such packages often connect to an external device by through vias, such that chips in the stack receive instructions by through vias that pass through one or more other chips in the stack, and transmit data by through vias that pass through the same one or more other chips. This may cause different amounts of delay based on the location of a chip in the stack. These different amounts of delay may cause undesirable operation of a semiconductor device.

### SUMMARY

According to one embodiment, a semiconductor package includes a first connection terminal group configured to receive a first signal group from the outside of the semiconductor package; a second connection terminal group configured to transmit a second signal group to the outside of the semiconductor package; a first chip connected to the first connection terminal group; and a second chip connected to the second connection terminal group, and configured to receive the first and second signal groups from the first chip.

In one embodiment, the first chip and the second chip are connected by a through via.

In one embodiment, long sides of the respective first and second chips are disposed to be perpendicular to a surface on which the first connection terminal group and the second connection terminal group are disposed.

In one embodiment, the first chip and the second chip are connected to the first connection terminal group and the second connection terminal group via bonding wires, respectively.

In one embodiment, the first chip is directly connected to the first connection terminal group, and the second chip is connected to the second connection terminal group via bonding wires.

In one embodiment, the first chip and the second chip are directly connected to the first connection terminal group and the second connection terminal group, respectively.

In one embodiment, the semiconductor package further includes at least one third chip connected to the first chip and the second chip by through vias between the first chip and the second chip.

In one embodiment, the first signal group includes a command signal, an address signal, and a memory clock signal.

In one embodiment, the second signal group includes a data signal and a data strobe signal.

In one embodiment, the first chip and the second chip each include a dynamic random access memory (DRAM).

According to another embodiment, a semiconductor package includes a first chip; and a second chip electrically connected to the first chip. The first chip is configured to transmit a data signal to the outside of the semiconductor package via the second chip, and the second chip is configured to receive a command signal from the outside of the semiconductor package via the first chip.

In one embodiment, the semiconductor package may further include a first ball group configured to receive the command signal from the outside; and a second ball group configured to transmit the data signal to the outside.

The first chip may be directly connected to the first ball group, and the second chip may be connected to the second ball group through a bonding wire.

The first chip and second chip may be connected to each other by a plurality of through vias.

In one embodiment, a semiconductor package, includes: a plurality of semiconductor chips consecutively electrically connected to each other, the plurality of semiconductor chips including a first end chip and a second end chip; a first set of first external connection terminals for connecting outside the plurality of semiconductor chips, the first set of first external connection terminals electrically connected to the first end chip; and a second set of second external connection terminals for connecting outside the plurality of semiconductor chips, the second set of second external connection terminals electrically connected to the second end chip. The first end chip is electrically between the first set of first external connection terminals and the second end chip, and the second end chip is electrically between the second set of second external connection terminals and the first end chip. The first set of first external connection terminals includes terminals configured to receive external signals, and the second set of second external connection terminals includes terminals configured to transmit signals outside of the plurality of semiconductor chips in response to the received external signals.

In one embodiment, a delay between the first set of first external connection terminals receiving the external signals and the second set of second external connection terminals transmitting signals in response to the received external signals for an access to a first chip of the plurality of semiconductor chips is the same as a delay between the first set of first external connection terminals receiving the external signals and the second set of second external connection terminals transmitting signals in response to the received external signals for an access to a second chip of the plurality of semiconductor chips.

In one embodiment, the first end chip includes pads directly connected to the first set of first external connection terminals; and the second end chip includes pads connected to the second set of second external connection terminals either directly or through bonding wires.

In one embodiment, through vias electrically connect the plurality of semiconductor chips to each other, such that the first end chip is at a bottom of a stack of semiconductor chips including the plurality of semiconductor chips, and the second end chip is at a top of the stack of semiconductor chips including the plurality of semiconductor chips.

One or more additional semiconductor chips may be between the first end chip and the second end chip. The one or more additional semiconductor chips may electrically connect to the first set of first external connection terminals through the first end chip, and the one or more additional semiconductor chips may electrically connect to the second set of second external connection terminals through the second end chip.

Numerical values, as well as terms such as “same,” “planar,” or “coplanar,” as used herein when referring to orientation, layout, location, shapes, sizes, amounts, times, or other measures do not necessarily mean an exactly identical orientation, layout, location, shape, size, amount, times, or other measure, but are intended to encompass nearly identical orientation, layout, location, shapes, sizes, amounts, times, or other measures within acceptable variations that may occur, for example, due to manufacturing processes or typical operational variances.

In one embodiment, the first set of first external connection terminals includes terminals configured to receive external command signals; and the second set of second external connection terminals includes terminals configured to transmit data signals outside of the plurality of semiconductor chips in response to the received external command signals.

### BRIEF DESCRIPTION OF THE DRAWINGS

Exemplary embodiments will be more clearly understood from the following detailed description taken in conjunction with the accompanying drawings in which:

FIG. 1 is a block diagram of a memory system according to one exemplary embodiment;

FIG. 2 is an exemplary block diagram of a memory device of FIG. 1, according to one embodiment;

FIG. 3 is a conceptual diagram of a semiconductor package including the memory device such as described in FIG. 2 according to one exemplary embodiment;

FIG. 4 is a conceptual diagram three-dimensionally illustrating a semiconductor package including the memory device such as described in FIG. 2 according to one exemplary embodiment;

FIG. 5 is a diagram illustrating an exemplary internal structure of the semiconductor package of FIG. 3 according to one embodiment;

FIG. 6 is a diagram illustrating an exemplary internal structure of the semiconductor package of FIG. 3 according to another embodiment;

FIG. 7 is a diagram illustrating an exemplary internal structure of the semiconductor package of FIG. 3 according to another embodiment;

FIG. 8 is a diagram illustrating an exemplary state in which a plurality of semiconductor packages such as that shown in FIG. 5 or 7 may be integrated according to one embodiment;

FIG. 9 is a diagram illustrating an exemplary state in which a plurality of semiconductor packages such as that shown in FIG. 6 may be integrated according to one embodiment;

FIG. 10 is a block diagram of an exemplary system including the memory device of FIG. 1 according to one embodiment;

FIG. 11 is a block diagram of an exemplary system including the memory device of FIG. 1 according to another embodiment;

FIG. 12 is a block diagram of an exemplary system including the memory device of FIG. 1 according to another embodiment;

FIG. 13 is a block diagram of an exemplary system including the memory device of FIG. 1 according to another embodiment;

FIG. 14 is a block diagram of an exemplary system including the memory device of FIG. 1 according to another embodiment; and

FIG. 15 is a block diagram of an exemplary system including the memory device of FIG. 1 according to another embodiment.

### DETAILED DESCRIPTION

The disclosure now will be described more fully hereinafter with reference to the accompanying drawings, in which various embodiments are shown. This invention may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless the context indicates otherwise, these terms are only used to distinguish one element from another. For example, a first chip could be termed a second chip, and, similarly, a second chip could be termed a first chip without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

FIG. 1 is a block diagram of a memory system 10 according to one exemplary embodiment.

Referring to FIG. 1, the memory system 10 may be embodied, for example, as an electronic device or a portable device. The portable device may be, for example, a cellular phone, a smart phone, or a tablet personal computer (PC).

The memory system 10 includes a host 100, a memory controller 150, and a memory device 200.

The host 100 may request the memory controller 150 to read or write desired data so as to exchange the data with the memory controller 150. For example, the host 100 may be embodied as an application processor.

The memory controller 150 generates a command signal CMD of FIG. 2 and an address signal ADD of FIG. 2 of the desired data, in response to a request from the host 100. The memory controller 150 receives a system clock signal from the host 100 and generates a memory clock signal CK of FIG. 2. The memory controller 150 may transmit a write data signal WD of FIG. 2 to the memory device 200, in synchronization with the memory clock signal CK. In this case, the memory controller 150 may encode the write data signal WD, for example, by performing error correction code (ECC) coding, and transmit a result of encoding the write data signal WD.

The memory controller 150 may receive a data signal DQ and a data strobe signal DQS of FIG. 2 from the memory device 200, and transmit the data signal DQ to the host 100, in synchronization with the data strobe signal DQS. In this case, the memory controller 150 may decode a read data signal RD, for example, by performing ECC decoding, and transmit a result of decoding the read data signal RD.

The memory device 200 may store the write data signal WD or output the read data signal RD, in response to the command signal CMD, the address signal ADD, and the memory clock signal CK from the memory controller 150. The memory device 200 may be embodied as a dynamic random access memory (DRAM) but is not limited thereto.

FIG. 2 is an exemplary block diagram of the memory device 200 of FIG. 1, according to one embodiment.

Referring to FIGS. 1 and 2, the memory device 200 may include a control logic 20, a refresh counter 31, a row multiplexer 33, a plurality of row buffers 35, a plurality of row decoders 37, a bank control logic 39, a plurality of column buffers 41, a plurality of column decoders 43, a plurality of banks 50, an input/output gate 55, an output driver 57, and an input buffer 59.

The control logic 20 may control each of various elements (e.g., the refresh counter 31, the row multiplexer 33, the bank control logic 39, or the plurality of column buffers 41), in response to a plurality of signals (e.g., the memory clock signal CK, the command signal CMD, and the address signal ADD).

Also, the control logic 20 may output the data strobe signal DQS via the input/output gate 55 for synchronization of read data RD.

The command signal CMD may be understood as a combination of a plurality of commands, e.g., commands CS, RAS, CAS, and/or WE. In one embodiment, the command signal CMD may be transmitted from the memory controller 150.

The address signal ADD may include information regarding a physical address of a cell that stores data that is to be read or written.

The control logic 20 may include an address command decoder 23. In one embodiment, the address command decoder 23 may be disposed outside the control logic 20, but the inventive concept is not limited thereto.

The address command decoder 23 may decode the command signal CMD that is a combination of a plurality of commands, e.g., command CS, RAS, CAS, and/or WE, based on the memory clock signal CK, and may generate a command and/or an address for controlling each of various elements (e.g., the refresh counter 31, the row multiplexer 33, the bank control logic 39, or the plurality of column buffers 41), based on a result of decoding the command signal CMD.

For example, in order to read data from the plurality of banks 50, the address command decoder 23 may output an active command, a read command, etc. In this case, an address signal, e.g., a row address and a column address, of a target cell storing data may be also output.

In one embodiment, the address command decoder 23 may generate a refresh command (e.g., an auto-refresh command) for performing a refresh operation by decoding the command signal CMD.

The refresh counter 31 may generate a row address according to the refresh command output from the address command decoder 23.

The row multiplexer 33 may select the row address generated by the refresh counter 31 or the row address output from the control logic 20, according to a selection signal (not shown).

In one embodiment, when the refresh operation is performed, the row multiplexer 33 may select the row address generated by the refresh counter 31.

In another embodiment, when a normal memory access operation (e.g., a read operation or a write operation) is performed, the row multiplexer 33 may select the row address output from the control logic 20.

Each of the plurality of row buffers 35 may buffer the row address output from the row multiplexer 33. In one embodiment, the plurality of row buffers 35 may be embodied as one row buffer, but the inventive concept is not limited thereto.

A row decoder 37 corresponding to a bank selected by the bank control logic 39 among the plurality of row decoders 37 may decode a row address output from a row buffer 35 corresponding to the selected bank among the plurality of row buffers 35.

In one embodiment, the plurality of row decoders 37 may be embodied as one row decoder, but the inventive concept is not limited thereto.

In another embodiment, each of the plurality of row decoders 37 may process a particular bit of a received row address as a ‘don't care’ bit, thereby activating more word lines for one refresh cycle.

The bank control logic 39 may select a bank for performing the normal memory access operation or the refresh operation among the plurality of banks 50, under control of the control logic 20.

In one embodiment, the control logic 20 may select a bank for performing the refresh operation among the plurality of banks 50.

Each of the plurality of column buffers 41 may buffer a column address output from the control logic 20. In one embodiment, the plurality of column buffers 41 may be embodied as one column buffer, but the inventive concept is not limited thereto.

A column decoder 43 corresponding to a bank selected by the bank control logic 39 among the plurality of column decoders 43 may decode a column address output from a column buffer 41 corresponding to the selected bank among the plurality of column buffers 41.

In one embodiment, the plurality of column decoders 43 may be embodied as one column decoder, but the inventive concept is not limited thereto.

Each of the plurality of banks 50 may include a memory cell array 51 that is labeled as a bank Bank0 to a bank BankN, and a sense amplifier & write driver block 53.

For convenience of explanation, a case in which the plurality of banks 50 are embodied as different layers is described, but the inventive concept is not limited by the structure and arrangement of the plurality of banks 50.

The memory cell array 51 includes a plurality of word lines (or row lines), a plurality of bit lines (or column lines), and a plurality of memory cells for storing data.

The sense amplifier & write driver block 53 may function as a sense amplifier configured to sense and amplify a change of a voltage of each of bit lines when the memory device 200 performs a read operation.

The sense amplifier & write driver block 53 may also function as a write driver configured to drive each of bit lines included in the memory cell array 51 when the memory device 200 performs a write operation.

The input/output gate 55 may transmit a read data signal RD or other signals output from the sense amplifier & write driver block 53 to the output driver 57 according to a column selection signal output from one of the plurality of column decoders 43. The input/output gate 55 may output a data strobe signal DQS together with the read data signal RD, under control of the control logic 20.

In one embodiment, the input/output gate 55 may transmit a write data signal WD or other signals received via the input buffer 59 to the sense amplifier & write driver block 53, according to the column selection signal.

The read data signal RD and the write data signal WD will be hereinafter referred collectively to as a ‘data signal DQ’.

The output driver 57 may output the read data signal RD transmitted from the input/output gate 55 to the outside of the memory device 200. The input buffer 59 may transmit the write data signal WD received from the outside of the memory device 200 to the input/output gate 55.

FIG. 3 is a conceptual diagram of a semiconductor package 300 including a memory device such as memory device 200 of FIG. 2 according to one exemplary embodiment.

Referring to FIGS. 2 and 3, the semiconductor package 300 may include a plurality of semiconductor devices 330, 340, 350, and 360 that are sequentially stacked on a semiconductor package substrate 310. The semiconductor devices 330, 340, 350, and 360, may be semiconductor chips, for example. The semiconductor package 300 may further include a plurality of connection terminals, such as balls 320, configured to exchange a signal between the semiconductor package 300 and the outside. As such, the balls 320 may be referred to as external connection terminals. Each of the plurality of semiconductor devices 330 to 360 may correspond to the memory device 200. The term “semiconductor device” may be used to describe devices 330 to 360, and may also be used herein to generally refer to a device such as semiconductor package 300.

The semiconductor package 300 may be embodied as a package-on-package (PoP), ball grid arrays (BGAs), chip-scale packages (CSPs), a plastic leaded chip carrier (PLCC), a plastic dual in-line package (PDIP), a chip-on board (COB), a ceramic dual in-line package (CERDIP), a plastic metric quad flat pack (MQFP), a thin quad flat pack (TQFP), a small-outline integrated circuit (SOIC), a shrink small outline package (SSOP), a thin small outline (TSOP), a system-in package (SIP), a multi-chip package (MCP), a wafer-level package (WLP), a wafer-level processed stack package (WSP), etc.

In one embodiment, some of the plurality of semiconductor devices 330 to 360 (e.g., the chip #1 330) may include all the elements of the memory device 200 illustrated in FIG. 2, and the other semiconductor devices (e.g., the chip #2 340 to the chip #4 360) may include only some elements of the memory device 200 (e.g., all the elements of the memory device 200 except for the control logic 20).

Electrical vertical connection means, e.g., a through-substrate via such as a through-silicon via (TSV), may be used to electrically connect the plurality of semiconductor devices 330 to 360.

FIG. 4 is a conceptual diagram three-dimensionally illustrating an exemplary semiconductor package 300′ including the memory device 200 of FIG. 2 according to one embodiment.

Referring to FIGS. 2 to 4, the semiconductor package 300′ includes a stacked structure of a plurality of semiconductor devices 330 to 360 connected via TSVs 370.

FIG. 5 is a diagram illustrating an exemplary internal structure of a semiconductor package 300-1 such as that shown in FIG. 3, according to one embodiment.

Referring to FIGS. 2 to 5, the semiconductor package 300-1 may include a first external conductive terminal group, such as ball group 320-1A, a second external conductive terminal group, such as ball group 320-1B, and a first chip 330-1 to a fourth chip 360-1. Although not shown, the semiconductor package 300-1 may further include the semiconductor package substrate 310 of FIG. 3 and the TSVs 370 of FIG. 4. As such, a signal may be exchanged among the first chip 330-1 to the fourth chip 360-1 via the TSVs 370.

The first ball group 320-1A may include a plurality of conductive terminals (e.g., balls) configured to receive a first signal group, which includes, for example, power, a command signal CMD, an address signal ADD, and a memory clock signal CK, from the memory controller 150. The second ball group 320-1B may include a plurality of conductive terminals (e.g., balls) configured to transmit/receive a second signal group, which includes, for example, a data signal DQ and a data strobe signal DQS. Although FIG. 5 illustrates that power is supplied to each of the first to fourth chips 330-1 to 360-1 via the first ball group 320-1A, the power may be supplied via the second ball group 320-1B.

Pads of the first chip 330-1 may be directly connected to the first ball group 320-1A corresponding to the pads of the first chip 330-1. The first chip 330-1 to the fourth chip 360-1 may be connected via TSVs 370 of FIG. 4 as described above. Pads of the fourth chip 360-1 may be connected to the second ball group 320-1B corresponding to the pads of the fourth chip 360-1 via a bonding wire 380-1.

The first signal group received via the first ball group 320-1A may be sequentially transmitted to the first chip 330-1, the second chip 340-1, the third chip 350-1, and the fourth chip 360-1.

The second signal group input to or output from each of the first chip 330-1 to the fourth chip 360-1 may sequentially pass through chips between each of the first chip 330-1 to the fourth chip 360-1 and the second ball group 320-1B, and the bonding wire 380-1, and then be input or output via the second ball group 320-1B. For example, when data stored in the first chip 330-1 is read, a read data signal RD output from the first chip 330-1 may pass through the second chip 340-1, the third chip 350-1, the fourth chip 360-1, and the bonding wire 380-1, and then be output via the second ball group 320-1B.

As shown for example in FIG. 5, the first chip 330-1, which may be referred to as a first end chip, is electrically between the first ball group 320-1A, also referred to herein as a first set of first external connection terminals, and the fourth chip 360-1. As also shown, the fourth chip 360-1, which may be referred to as a second end chip, is electrically between the first chip 330-1 (e.g., first end chip) and second ball group 320-1B, also referred to herein as a second set of second external connection terminals. As shown in FIG. 5, the first end chip may be connected to the first set of first external connection terminals without any chips connected therebetween, and the second end chip may be connected to the second set of second connection terminals without any chips connected therebetween. One or more chips may be connected between the first end chip and the second end chip.

When a signal is exchanged between adjacent chips, a delay time incurred for the command signal CMD, the address signal ADD, and the memory clock signal CK to pass through the TSV 370 between the adjacent chips will be defined as a command TSV delay tTSVCMD. A delay time incurred for the data signal DQ and the data strobe signal DQS to pass through the TSV 370 between the adjacent chips will be defined as a data TSV delay tTSVDQ.

A delay time between a point of time when each of the first chip 330-1 to the fourth chip 360-1 receives the command signal CMD, the address signal ADD, and the memory clock signal CK and a point of time when the data signal DQ and the data strobe signal DQS that correspond to the command signal CMD are output will be defined as a chip delay tAACHIP. A delay time incurred for the data signal DQ and the data strobe signal DQS to pass through the bonding wire 380-1 between the fourth chip 360-1 and the second ball group 320-1B will be defined as a bonding wire delay tWIRE. Also, it is assumed that the pads of the first chip 330-1 are directly connected to the corresponding first ball group 320-1A and no delay time is thus incurred.

Here, a total delay time tAA1 incurred for the semiconductor package 300-1 to read data stored in the first chip 330-1 is (tAACHIP+3*tTSVDQ+tWIRE). A total delay time tAA2 incurred for the semiconductor package 300-1 to read data stored in the second chip 340-1 is (tAACHIP+tTSVCMD+2*tTSVDQ+tWIRE).

A total delay time tAA3 incurred for the semiconductor package 300-1 to read data stored in the third chip 350-1 is (tAACHIP+2*tTSVCMD+tTSVDQ+tWIRE). A total delay time tAA4 incurred for the semiconductor package 300-1 to read data stored in the fourth chip 360-1 is (tAACHIP+3*tTSVCMD+tWIRE).

If it is assumed that both the command TSV delay tTSVCMD and the data TSV delay tTSVDQ are delayed by a TSV between adjacent chips and thus have the same value, the total delay times tAA1 to tAA4 have the same value, i.e., (tAACHIP+3*tTSVCMD+tWIRE) or (tAACHIP+3*tTSVDQ+tWIRE).

Therefore, since the total delay times tAA1 to tAA4 incurred for the semiconductor package 300-1 to read the data stored in the respective first to fourth chips 330-1 to 360-1 are the same, the differences between the total delay times in the first to fourth chips 330-1 to 360-1 are zero. This is because only the first ball group 320-1A is connected to the first chip 330-1 and the second ball group 320-1B is connected to the fourth chip 360-1. Thus, the second signal group is transmitted in a direction that is different from a direction in which the first signal group is transmitted, and the differences between the total delay times tAA1 to tAA4 in the respective first to fourth chips 330-1 to 360-1 are zero.

Accordingly, degradation in the performance of the semiconductor package 300-1 having an internal structure according to the current embodiment, caused by the differences between signal delay times in a plurality of respective chips therein may be minimized.

Although a case in which data stored in the semiconductor package 300-1 is read has been described above, the differences between signal delay times in the plurality of respective chips may be zero even during a data write operation.

FIG. 6 is a diagram illustrating an exemplary internal structure of a semiconductor package 300-2 such as that shown in FIG. 3 according to another embodiment.

Referring to FIGS. 2 to 6, in the semiconductor package 300-2, a second ball group 320-2B is located opposite to a first ball group 320-2A unlike in the semiconductor package 300-1 of FIG. 5. For example, one ball group may be located at a bottom of the semiconductor package 300-2, and another ball group may be located at a top of the semiconductor package 300-2. In this example, pads of a fourth chip 360-2 are connected to corresponding balls of the second ball group 320-2B without using bonding wires, respectively. The semiconductor package 300-2 may be substantially the same as the semiconductor package 300-1 of FIG. 5 except for the difference described above.

Here, a total delay time tAA1 incurred for the semiconductor package 300-2 to read data stored in the first chip 330-2 is (tAACHIP+3*tTSVDQ). A total delay time tAA2 incurred for the semiconductor package 300-2 to read data stored in the second chip 340-2 is (tAACHIP+tTSVCMD+2*tTSVDQ).

A total delay time tAA3 incurred for the semiconductor package 300-2 to read data stored in a third chip 350-2 is (tAACHIP+2*tTSVCMD+tTSVDQ). A total delay time tAA4 incurred for the semiconductor package 300-2 to read data stored in the fourth chip 360-2 is (tAACHIP+3*tTSVCMD).

If it is assumed that both a command TSV delay tTSVCMD and a data TSV delay tTSVDQ are incurred by a TSV between adjacent chips and thus have the same value, the total delay times tAA1 to tAA4 have the same value, i.e., (tAACHIP+3*tTSVCMD) or (tAACHIP+3*tTSVDQ).

Accordingly, the total delay times incurred for the semiconductor package 300-2 to read the data stored in the respective first chip 330-2 to the fourth chip 360-2 are the same, and the differences between the delay times in the respective first chip 330-2 to the fourth chip 360-2 are zero.

However, bonding wires are not used and a bonding wire delay tWIRE is thus not incurred in the semiconductor package 300-2 of FIG. 6, unlike in the semiconductor package 300-1 of FIG. 5.

FIG. 7 is a diagram illustrating an exemplary internal structure of a semiconductor package 300-3 such as that shown in FIG. 3 according to another embodiment.

Referring to FIGS. 2 to 7, in the semiconductor package 300-3, a first chip 330-3 to a fourth chip 360-3 are stacked such that long sides thereof are perpendicular to a surface on which a first ball group 320-3A and a second ball group 320-3B are disposed, unlike in the semiconductor package 300-1 of FIG. 5. A first chip 330-3 and a fourth chip 360-3 are connected to a first ball group 320-3A and a second ball group 320-3B corresponding thereto via first bonding wires 380-3A and second bonding wires 380-3B, respectively. The semiconductor package 300-3 is substantially the same as the semiconductor package 300-1 of FIG. 5 except for the difference described above.

A delay time incurred for a command signal CMD, an address signal ADD, and a memory clock signal CK to pass through a bonding wire 380-3A will be defined as a first bonding wire delay tWIRE1. A delay time incurred for a data signal DQ and a data strobe signal DQS to pass through a second bonding wire 380-3B will be defined as a second bonding wire delay tWIRE2.

Here, a total delay time tAA1 incurred for the semiconductor package 300-3 to read data stored in the first chip 330-3 is (tAACHIP+3*tTSVDQ+tWIRE1+tWIRE2). A total delay time tAA2 incurred for the semiconductor package 300-3 to read data stored in a second chip 340-3 is (tAACHIP+tTSVCMD+2*tTSVDQ+tWIRE1+tWIRE2).

A total delay time tAA3 incurred for the semiconductor package 300-3 to read data stored in a third chip 350-3 is (tAACHIP+2*tTSVCMD+tTSVDQ+tWIRE1+tWIRE2). A total delay time tAA4 incurred for the semiconductor package 300-3 to read data stored in a fourth chip 360-3 is (tAACHIP+3*tTSVCMD+tWIRE1+tWIRE2).

If it is assumed that both a command TSV delay tTSVCMD and a data TSV delay tTSVDQ are incurred by a TSV between adjacent chips and thus has the same value, the total delay times tAA1 to tAA4 have the same value, i.e., (tAACHIP+3*tTSVCMD+tWIRE1+tWIRE2) or (tAACHIP+3*tTSVDQ+tWIRE1+tWIRE2).

As such, the total delay times incurred for the semiconductor package 300-3 to read the data stored in the respective first chip 330-3 to the fourth chip 360-3 are the same and the differences between the total delay times are zero.

Also, when the first chip 330-3 to the fourth chip 360-3 are vertically stacked as illustrated in FIG. 7, the area of a bottom surface of the semiconductor package 300-3 on which the first ball group 320-3A and the second ball group 320-3B are disposed is smaller than in FIGS. 5 and 6, thereby increasing the degree of integration of the semiconductor package 300-3.

FIG. 8 is a diagram illustrating an exemplary state in which a plurality of semiconductor packages 300A such as shown in FIG. 5 or 7 may be integrated according to one embodiment.

Referring to FIGS. 5, 7, and 8, the semiconductor packages 300A may be arranged in a line in a direction indicated by an arrow A. The semiconductor packages 300A may share a command signal CMD, an address signal ADD, a memory clock signal CK, a data signal DQ, and a data strobe signal DQS, but the inventive concept is not limited thereto.

Each of the semiconductor packages 300A may correspond to the semiconductor package 300-1 of FIG. 5 or the semiconductor package 300-3 of FIG. 7.

FIG. 9 is a diagram illustrating an exemplary state in which a plurality of semiconductor packages 300B such as shown in FIG. 6 may be integrated according to one embodiment.

Referring to FIGS. 6 and 9, the semiconductor packages 300B may be arranged in a line in a direction indicated by an arrow B. The semiconductor packages 300B may share a command signal CMD, an address signal ADD, a memory clock signal CK, a data signal DQ, and a data strobe signal DQS, but the inventive concept is not limited thereto.

Each of the semiconductor packages 300B may correspond to the semiconductor package 300-2 of FIG. 6.

FIG. 10 is a block diagram of an exemplary system 400 including the memory device 200 of FIG. 1 according to one embodiment.

Referring to FIGS. 1, 5 to 7, and 10, the system 400 may be embodied as an electronic device, which may be for example a portable device. The portable device may be a cellular phone, a smart phone, or a tablet PC, for example.

The system 400 includes a processor 411 and a memory device 413. The memory device 413 may include the memory device 200 of FIG. 1.

In one embodiment, the memory device 413 may be packaged in a semiconductor package. In this case, the semiconductor package may be mounted on a system board (not shown). The semiconductor package may be understood as the semiconductor package 300-1 of FIG. 5, the semiconductor package 300-2 of FIG. 6, or the semiconductor package 300-3 of FIG. 7.

The processor 411 includes a memory controller 415 configured to control a data processing operation (e.g., a write operation or a read operation) of the memory device 413. The memory controller 415 is controlled by the processor 411 configured to control overall operations of the system 400. In one embodiment, the memory controller 415 may be connected between the processor 411 and the memory device 413. The processor 411 may correspond to the host 100 of FIG. 1, and the memory controller 415 may correspond to the memory controller 150 of FIG. 1.

Data stored in the memory device 413 may be displayed on a display unit 420 under control of the processor 411.

A radio transceiver 430 may transmit or receive a radio signal via an antenna ANT. For example, the radio transceiver 430 may transform the radio signal received via the antenna ANT into a signal to be processed by the processor 411. Thus, the processor 411 may process a signal output from the radio transceiver 430, and store the processed signal in the memory device 413 or display the processed signal on the display unit 420.

The radio transceiver 430 transforms a signal output from the processor 411 into a radio signal, and outputs the radio signal to the outside via the antenna ANT.

An input device 440 is a device via which a control signal for controlling an operation of the processor 411 or data that to be processed by the processor 411 is input, and may be embodied, for example, as a pointing device such as a touch pad and a computer mouse, or a keyboard.

The processor 411 may control the display unit 420 to display data output from the memory device 413, a radio signal output from the radio transceiver 430, or data output from the input device 440 on the display unit 420.

FIG. 11 is a block diagram of a system 500 including the memory device 200 of FIG. 1 according to another exemplary embodiment. Referring to FIGS. 1, 5 to 7, and 11, the system 500 may be embodied, for example, as a PC, a tablet PC, a net-book, an e-reader, a personal digital assistant (PDA), a portable multimedia player (PMP), an MP3 player, or an MP4 player.

The system 500 includes a processor 511 configured to control overall operations of the system 500, and a memory device 513. The memory device 513 may be understood as the memory device 200 of FIG. 1.

In one embodiment, the memory device 513 may be packaged in a semiconductor package. The semiconductor package may be mounted on a system board (not shown). The semiconductor package may be understood as the semiconductor package 300-1 of FIG. 5, the semiconductor package 300-2 of FIG. 6, or the semiconductor package 300-3 of FIG. 7.

The processor 511 may include a memory controller 515 configured to control an operation of the memory device 513. The processor 511 may correspond to the host 100 of FIG. 1, and the memory controller 515 may correspond to the memory controller 150 of FIG. 1.

The processor 511 may display data stored in the memory device 513 on a display unit 530 according to an input signal generated by an input device 520. For example, the input device 520 may be embodied as a pointing device such as a touch pad or a computer mouse, a keypad, or a keyboard.

FIG. 12 is a block diagram of a system 600 including the memory device 200 of FIG. 1 according to another exemplary embodiment. Referring to FIGS. 1, 5 to 7, and 12, the system 600 may be embodied as a memory card or a smart card.

The system 600 may include a memory device 613, a memory controller 611, and a card interface 620. The memory device 613 may be understood as the memory device 200 of FIG. 1.

In one embodiment, the memory device 613 may be packaged in a semiconductor package. The semiconductor package may be mounted on a system board (not shown). The semiconductor package may be understood as the semiconductor package 300-1 of FIG. 5, the semiconductor package 300-2 of FIG. 6, or the semiconductor package 300-3 of FIG. 7.

The memory controller 611 may control exchange of data between the memory device 613 and the card interface 620. The memory controller 611 may correspond to the memory controller 150 of FIG. 1.

In one embodiment, the card interface 620 may be a secure digital (SD) card interface or a multi-media card (MMC) interface but the inventive concept is not limited thereto.

The card interface 620 may interface exchange of data between a host and the memory controller 611 according to a protocol from the host.

When the system 600 is connected to the host such a computer, a digital camera, a digital audio player, a cellular phone, console video game hardware, or a digital set-top box, the host may exchange data stored in the memory device 613 with the card interface 620 via the memory controller 611.

FIG. 13 is a block diagram of a system 700 including the memory device 200 of FIG. 1 according to another exemplary embodiment. Referring to FIGS. 1, 5 to 7, and 13, the system 700 may be embodied as a digital camera or a portable device with a built-in digital camera.

The system 700 includes a processor 711 configured to control overall operations of the system 700, and a memory device 713. The memory device 713 may be understood as the memory device of FIG. 1

In one embodiment, the memory device 713 may be packaged in a semiconductor package. The semiconductor package may be mounted on a system board (not shown). The semiconductor package may be understood as the semiconductor package 300-1 of FIG. 5, the semiconductor package 300-2 of FIG. 6, or the semiconductor package 300-3 of FIG. 7.

An image sensor 720 of the system 700 transforms an optical image into a digital signal. The digital signal is stored in the memory device 713 or is displayed on a display unit 730, under control of the processor 711. The digital signal stored in the memory device 713 is displayed on the display unit 730 under control of the processor 711.

FIG. 14 is a block diagram of a system 800 including the memory device 200 of FIG. 1 according to another exemplary embodiment. Referring to FIGS. 1, 5 to 7, and 14, the system 800 includes a memory device 813, and a processor 811 configured to control overall operations of the system 800. The memory device 813 may be understood as the memory device 200 of FIG. 1.

In one embodiment, memory device 813 may be packaged in a semiconductor package. The semiconductor package may be mounted on a system board (not shown). The semiconductor package may be understood as the semiconductor package 300-1 of FIG. 5, the semiconductor package 300-2 of FIG. 6, or the semiconductor package 300-3 of FIG. 7.

The processor 811 includes a memory controller 815 configured to control an operation of the memory device 813. The processor 811 may be understood as the host 100 of FIG. 1, and the memory controller 815 may be understood as the memory controller 150 of FIG. 1.

The system 800 includes a memory 840 that may be used as an operation memory of the processor 811. The memory 840 may be embodied as a non-volatile memory such as a read only memory (ROM) or a flash memory.

A host connected to the system 800 may exchange data stored in the memory device 813 with the processor 811 via a host interface 830. In this case, the memory controller 815 may perform a function of a memory interface.

In one embodiment, the system 800 may further include an ECC block 820. The ECC block 820 that operates under control of the processor 811 detects and corrects an error in data read from the memory device 813 by the memory controller 815.

The processor 811 may control exchange of data among the ECC block 820, a host interface 830, and the memory 840 via a bus 801.

The system 800 may be embodied, for example, as a universal serial bus (USB) memory drive or a memory stick.

FIG. 15 is a block diagram of a system 900 including the memory device 200 of FIG. 1 according to another exemplary embodiment. A channel 901 may be understood as optical connection means. The optical connection means 901 may mean an optical fiber, an optical waveguide, or a medium via which an optical signal is transmitted.

Referring to FIGS. 1 and 15, the system 900 may include a first system 1000 and a second system 1100. The first system 1000 may include a first memory device 100a and an electrical-to-optical (E/O) conversion circuit 1010. The E/O conversion circuit 1010 converts an electrical signal output from the first memory device 100a into an optical signal, and outputs the optical signal to the second system 1100 via the optical connection unit 901.

The second system 1100 includes an optical-to-electrical (O/E) conversion circuit 1120 and a second memory device 100b. The O/E conversion circuit 1120 may convert an optical signal received via the optical connection unit 901 into an electrical signal, and transmit the electrical signal to the second memory device 100b.

The first system 1000 may further include an O/E conversion circuit 1020, and the second system 1100 may further include an E/O conversion circuit 1110.

When the second system 1100 transmits data to the first system 1000, the E/O conversion circuit 1110 may convert an electrical signal output from the second memory device 100b into an optical signal, and output the optical signal to the first system 1000 via the optical connection unit 901. The O/E conversion circuit 1020 converts an optical signal received via the optical connection unit 901 into an electrical signal, and transmits the electrical signal to the first memory device 100a. The structures and operations of the respective memory devices 100a and 100b are substantially the same as those of the memory device 200 of FIG. 1. Also, the memory devices 100a and 100b may be each embodied as a semiconductor package. Here, the semiconductor package may be understood as the semiconductor package 300-1 of FIG. 5, the semiconductor package 300-2 of FIG. 6, or the semiconductor package 300-3 of FIG. 7.

A semiconductor package according to the one or more embodiments disclosed herein is capable of minimizing degradation thereof, caused by the differences between signal delay times in a plurality of chips included in the semiconductor package.

While the disclosure has been particularly shown and described with reference to exemplary embodiments thereof, it will be understood that various changes in form and details may be made therein without departing from the spirit and scope of the following claims.

What is claimed is:

1. A semiconductor package comprising:
a first connection terminal group configured to receive a first signal group from the outside of the semiconductor package;
a second connection terminal group configured to transmit a second signal group to the outside of the semiconductor package;
a first chip connected to the first connection terminal group; and
a second chip connected to the second connection terminal group, and configured to receive the first and second signal groups from the first chip.

2. The semiconductor package of claim 1, wherein the first chip and the second chip are connected by a through via.

3. The semiconductor package of claim 1, wherein long sides of the respective first and second chips are disposed to be perpendicular to a surface on which the first connection terminal group and the second connection terminal group are disposed.

4. The semiconductor package of claim 3, wherein the first chip and the second chip are connected to the first connection terminal group and the second connection terminal group via bonding wires, respectively.

5. The semiconductor package of claim 1, wherein the first chip is directly connected to the first connection terminal group, and
the second chip is connected to the second connection terminal group via bonding wires.

6. The semiconductor package of claim 1, wherein the first chip and the second chip are directly connected to the first connection terminal group and the second connection terminal group, respectively.

7. The semiconductor package of claim 1, further comprising at least one third chip connected to the first chip and the second chip by through vias between the first chip and the second chip.

8. The semiconductor package of claim 1, wherein the first signal group comprises a command signal, an address signal, and a memory clock signal.

9. The semiconductor package of claim 1, wherein the second signal group comprises a data signal and a data strobe signal.

10. The semiconductor package of claim 1, wherein the first chip and the second chip each comprises a dynamic random access memory (DRAM).

11. A semiconductor package comprising:
a first chip; and
a second chip electrically connected to the first chip,
wherein the first chip is configured to transmit a data signal to the outside of the semiconductor package via the second chip, and
wherein the second chip is configured to receive a command signal from the outside of the semiconductor package via the first chip.

12. The semiconductor package of claim 11, further comprising:
a first ball group configured to receive the command signal from the outside; and
a second ball group configured to transmit the data signal to the outside.

13. The semiconductor package of claim 12, wherein the first chip is directly connected to the first ball group, and
the second chip is connected to the second ball group via a bonding wire.

14. The semiconductor package of claim 12, wherein the first chip and the second chip are connected to each other by a plurality of through vias.

15. A semiconductor package, comprising:
a plurality of semiconductor chips consecutively electrically connected to each other, the plurality of semiconductor chips including a first end chip and a second end chip;
a first set of first external connection terminals for connecting outside the plurality of semiconductor chips, the first set of first external connection terminals electrically connected to the first end chip; and
a second set of second external connection terminals for connecting outside the plurality of semiconductor chips, the second set of second external connection terminals electrically connected to the second end chip;
wherein:
the first end chip is electrically between the first set of first external connection terminals and the second end chip, and the second end chip is electrically between the second set of second external connection terminals and the first end chip;
the first set of first external connection terminals includes terminals configured to receive external signals; and
the second set of second external connection terminals includes terminals configured to transmit signals outside of the plurality of semiconductor chips in response to the received external signals.

16. The semiconductor package of claim 15, wherein:
a delay between the first set of first external connection terminals receiving the external signals and the second set of second external connection terminals transmitting signals in response to the received external signals for an access to a first chip of the plurality of semiconductor chips is the same as a delay between the first set of first external connection terminals receiving the external signals and the second set of second external connection terminals transmitting signals in response to the received external signals for an access to a second chip of the plurality of semiconductor chips.

17. The semiconductor package of claim 15, wherein:
the first end chip includes pads directly connected to the first set of first external connection terminals; and
the second end chip includes pads connected to the second set of second external connection terminals either directly or through bonding wires.

18. The semiconductor package of claim 15, further comprising:
through vias electrically connecting the plurality of semiconductor chips to each other, such that the first end chip is at a bottom of a stack of semiconductor chips including the plurality of semiconductor chips, and the second end chip is at a top of the stack of semiconductor chips including the plurality of semiconductor chips.

19. The semiconductor package of claim 18, wherein the plurality of semiconductor chips further comprises:
one or more additional semiconductor chips between the first end chip and the second end chip, wherein:
the one or more additional semiconductor chips electrically connect to the first set of first external connection terminals through the first end chip, and
the one or more additional semiconductor chips electrically connect to the second set of second external connection terminals through the second end chip.

20. The semiconductor package of claim 15, wherein:
the first set of first external connection terminals includes terminals configured to receive external command signals; and
the second set of second external connection terminals includes terminals configured to transmit data signals outside of the plurality of semiconductor chips in response to the received external command signals.
